(19) United States
(12) Patent Application Publication
(10) Pub. No.: US 2002/0073363 A1
(43) Pub. Date: Jun. 13, 2002

(54) Data processing system

(76) Inventors: Igor Anatolievich Abrosimov, St. Petersburg (RU); Ilya Valerievich Klotchkov, St. Petersburg (RU)

Correspondence Address: Ellen Marcie Emas, BURNS, DOANE, SWECKER & MATHIS, L.L.P., P.O. Box 1404, Alexandria, VA, 22313-1404, US

(21) Appl. No.: 10/066,775

(22) Filed: Feb. 6, 2002

Related U.S. Application Data
(63) Continuation of application No. PCT/RU01/00234, filed on Jun. 6, 2001.
(60) Provisional application No. 60/209,613, filed on Jun. 6, 2000.

(51) Int. Cl. H03K 19/003

(52) U.S. Cl. 714/42; 714/25

(57) ABSTRACT

The present invention relates generally to data processing systems, in particular, to high speed data communication and chip-to-chip data transfer.

The data transferring apparatus comprises:

a data input and data output;

a plurality of data transferring sections operable in parallel for transferring data and a circuit for synchronising said parallel data transferring sections;

a programmable frequency clock generator for generating a clock signal, said programmed frequency including a full-frequency and low-frequency, the low frequency being a quotient of the full frequency and the number of said data transferring sections;

wherein said data transferring sections operate at said low frequency; while said input and output data are provided at said full frequency.

Preferably, the data transferring apparatus further comprises a multiplexer that receives data from said data transferring sections at said low frequency and provides multiplexed output data at said full frequency.

The invention is particularly applicable to computer-controlled automatic test systems for testing integrated circuits, more particularly, to memory test systems which interface with high speed protocol memories such as synchronous DRAM, in particular DDR.

### BACKGROUND OF THE INVENTION

1. Technical Field of the Invention

This invention relates generally to data processing systems, especially, for high speed data communication and chip-to-chip data transfer. In particular, the invention is applicable for testing integrated circuits, more particular, to memory test systems which interface with high speed protocol memories such as synchronous dynamic random access memories, in particular, double data rate (DDR) memories.

2. Description of the Related Art

Present complementary metal oxide semiconductor (CMOS) synchronous dynamic random access memory (SDRAM) circuits are frequently used in a variety of applications including desk top and portable computer systems. Advances in system technology require ever increasing clock rates and memory bus widths to achieve high data rates. Both of these methods impose equally demanding limitations on data generating and processing systems, such as memory testers, that must guarantee functionality of the memory circuits under all conditions.

Test systems are required in memory production and assembly to identify defective cells and defective memories. Most memories manufactured have some defects. The test systems comprise a large proportion of the total capital equipment cost of memory fabrication plants. Previous memory design-for-test circuits have logically combined multiple data bits extracted from a memory array in parallel to produce an equivalent compressed bit. The memory tester evaluated this representative compressed bit of the multiple data bits, thereby reducing the apparent size of the memory circuit to be tested. But this test method is still inefficient due to the greater operating speed of state-of-the-art memory circuit than of current memory testers. Current memory testers, therefore, significantly constrain memory circuit production. An upgrade of memory testers, however, would require a significant expenditure of capital.

This limitation of data processing systems, such as memory testers, is particularly apparent for synchronous dynamic random access memory (SDRAM) circuits or similar circuits operating in burst mode. An SDRAM circuit receives initial row and column address signals in a burst read cycle. An internal address counter increments this initial address to produce parallel sequences of data bits corresponding to each bit position of a data word in synchronization with a system clock signal. Although, the SDRAM circuit may potentially operate faster than the memory tester, both input and output data rates of the sequences of data bits are limited by the speed of the memory tester. Thus, the memory tester severely limits SDRAM production even with highly parallel Design For Testability (DFT) circuits of the prior art.

One aspect of the forgoing problem is that conventional data processing systems such as memory testers cannot generate input data at a speed required for SDRAM operation.

Accordingly, the present invention is directed to the problem of providing a data processing system capable of generating and processing data for high speed memory devices at suitable rates. The invention can be well applicable for high speed data processing in other fields.

### BRIEF SUMMARY OF THE INVENTION

Thus, in most general aspect of the invention, a data processing system comprises:

a data transferring apparatus having a data input and data output; a plurality of data transferring sections operable in parallel for transferring data; and a circuit for synchronising said parallel data transferring sections; and

a programmable frequency clock generator for generating a clock signal, wherein said programmed frequency includes a full-frequency and a low-frequency, the low frequency being a quotient of the full frequency and the number of said data transferring sections;

wherein said data transferring sections operate at said low frequency; while said input and output data are provided at said full frequency.

According to the first embodiment of the invention, the data processing system is adapted for data transmission and comprises:

a data transmitter comprising a plurality of data transmitting sections operable in parallel for transmitting data, wherein the data transmitter further comprises a circuit for synchronising said parallel data transmitting sections;

a programmable frequency clock generator for generating a clock signal, wherein said programmed frequency includes a full-frequency and a low-frequency, the low frequency being a quotient of the full frequency and a number of said data transmitting sections;

a multiplexer that receives data from said data transmitting sections at said low frequency and provides multiplexed output data at said full frequency.

According to another embodiment, the data processing system is adapted for receiving data and comprises:

a data receiver comprising a data input and data output, a plurality of data receiving sections operable in parallel for receiving data, and a circuit for synchronising said parallel data receiving sections;

a programmable frequency clock generator for generating a clock signal, wherein said programmed frequency includes a full-frequency and a low frequency, the low frequency being a quotient of the full frequency and a number of said data transmitting sections,

wherein said data receiving sections operate at said low frequency; while said output data are transmitted and received at said full frequency.

Preferably, the data receiving sections include

a plurality of registers for latching data and supplying latched received data to a plurality of logic devices.

In a particularly preferable embodiment, the data processing system is used for supplying test data for accessing a memory device under test at a speed appropriate for high speed synchronous memories such as SDRAM and retrieving the resulted test data at a rate that also would not limit the operation of the memory. In this case, the data processed will be test data generated by an algorithmic pattern generator.

Thus, in another aspect, a test system is proposed comprising:

an algorithmic pattern generator having a plurality of test data generating sections operable in parallel for generating test data for accessing a memory device under test, wherein the pattern generator additionally comprises a circuit for synchronising said parallel data generating sections;

a programmable frequency clock generator for generating a clock signal, wherein said programmed frequency includes a full-frequency and a low-frequency, the low frequency being a quotient of the full frequency and a number of said test data generating sections;

a multiplexer that receives said test data from said data generating sections at said low frequency and provides multiplexed data for accessing device under test (DUT) at said full frequency;

a plurality of registers for latching data from the DUT and supplying latched fault data to a plurality of fault logic devices;

wherein said test data generating sections, said registers and said fault logic devices operate at said low frequency; while said device under test is accessed at said full frequency.

For example, said low frequency may be equal to a half of said full frequency for SDRAM memories, and is equal to a one forth of the full frequency for DDR memories.

The proposed data processing system may be implemented in a test system which allows both functional and parametric testing of SDRAMs and supports all SDRAM-specific operations for 16M, 64M, 256M and higher chips. Preferably, said programmable system clock operates at 166 MHz and higher. Test data can be generated and faults can be stored for every clock period, while 72 bits of data and 32 bits of address are generated.

### BRIEF DESCRIPTION OR THE SEVERAL VIEWS OF THE DRAWINGS

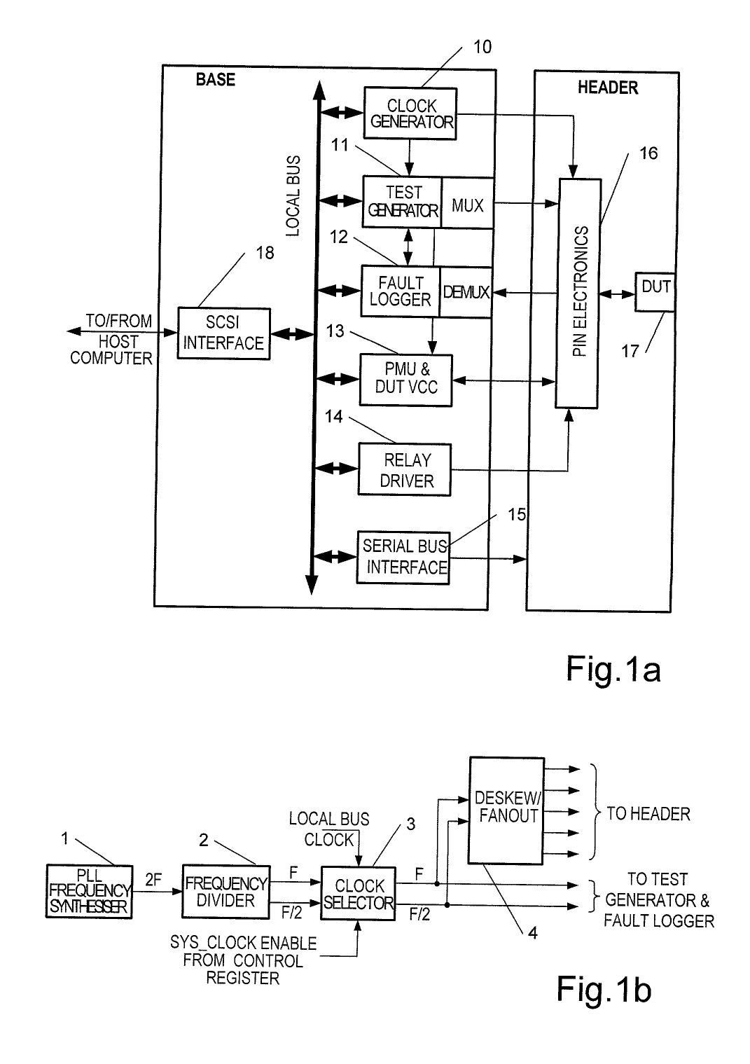

A functional diagram of a conventional test system is presented in FIG. 1a. The test system comprises a base and a test head, usually called header. The base provides all the algorithmic functionality, while the head conditions the signals applied to the Device Under Test (DUT). There may be many different heads developed to accommodate DUTs of different type or to meet specific customer demands.

The tester base comprises clock generator 10, test generator 11, fault logger 12, parametric measuring unit (PMU) 13, relay drive 14 and serial bus interface 15. The base has also a Small Computer System Interface (SCSI) 18 for interfacing with a controlling computer. According to the present invention, test generator 11 and fault logger 12 operate at a low frequency, therefore, test generator 11 is additionally provided with a multiplexer, while fault logger 12 is provided with demultiplexer. The test head comprises pin electronics 16 to provide signals to/from DUT 18.

As has been mentioned above, clock generator 10 which is shown in more detail in FIG. 1b, generates both full-frequency and half-frequency system clock and distributes it to all units of the tester that need it. The half-frequency clock is required because complicated logical functions can not be executed at full-frequency speed (166 MHz). So these functions are usually performed at half-frequency rate, and generated data are then multiplexed in the DUT's proximity as described in detail later.

To generate the required clocks with programmable frequency, Phase Locked Loop (PLL) frequency synthesiser 1 can be used along with the frequency divider 2. The synthesiser can be built of Synergy SY89429A chip (please refer for details to the corresponding datasheet, see http:/www.micrel.com/_PDF/Synergy-PDF/sy89429a.pdf) available from Micrel Semiconductor, San Jose, Calif., USA). Any other suitable clock systems of programmable frequency can be used for this purpose, for example the one described in U.S. Pat. No. 5,065,415 for dividing the frequency of a supplied high frequency signal directly into lower frequency signals.

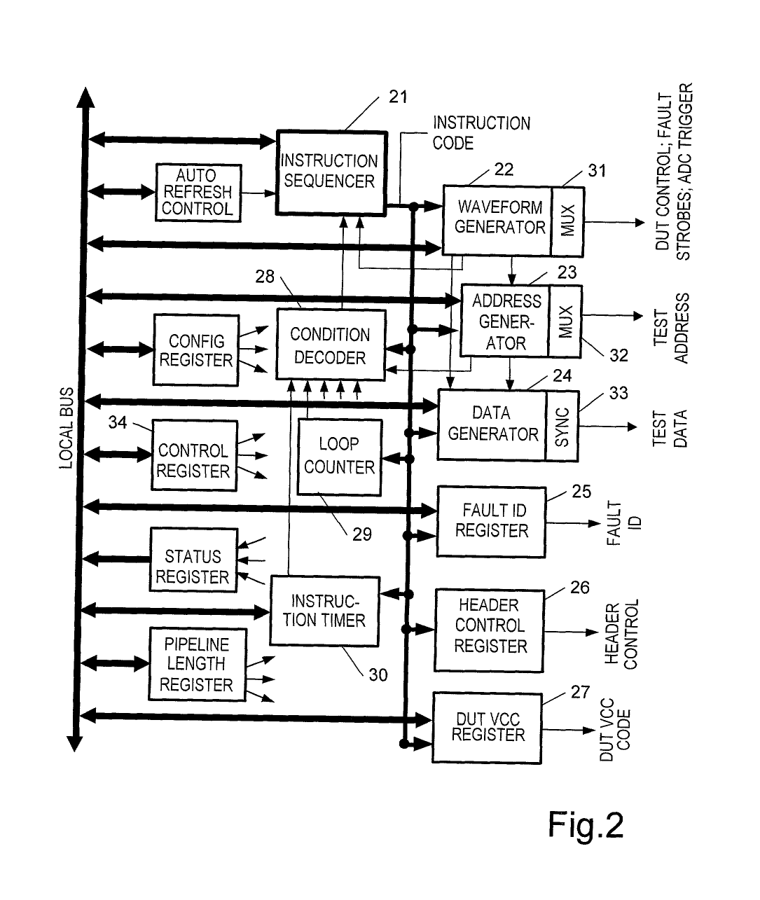

For tester configuration purposes it is required that the system clock can be made synchronous to local bus clock in halted mode. Clock selector 3 implements this function under control of the SYS_CLOCK bit of control register designated by position 34 in FIG. 2 which shows in greater detail the test generator 11 of FIG. 1a. When this control bit is asserted (SYS_CLOCK is enabled), the clocks are sourced from synthesiser 1. When the bit is deasserted (SYS_CLOCK is disabled), the half-frequency clock (F/2) is switched to Local Bus clock, thus allowing configuring the tester; the full-frequency clock (F) is disabled.

The operation of the above logical units of the tester as presented in FIG. 1a is described in details with reference to accompanying drawings.

A block diagram of the test generator is shown in FIG. 2. The test generator generates a test that consists of a sequence of instructions implementing the test algorithm. A conventional test generator comprises instruction sequencer 21 that provides instructions to waveform generator 22, address generator 23, data generator 24, fault register 25, header control register 26, DUT register 27, and also condition decoder 28, loop counter 29 instruction timer 30 and other circuitry as shown in FIG. 2.

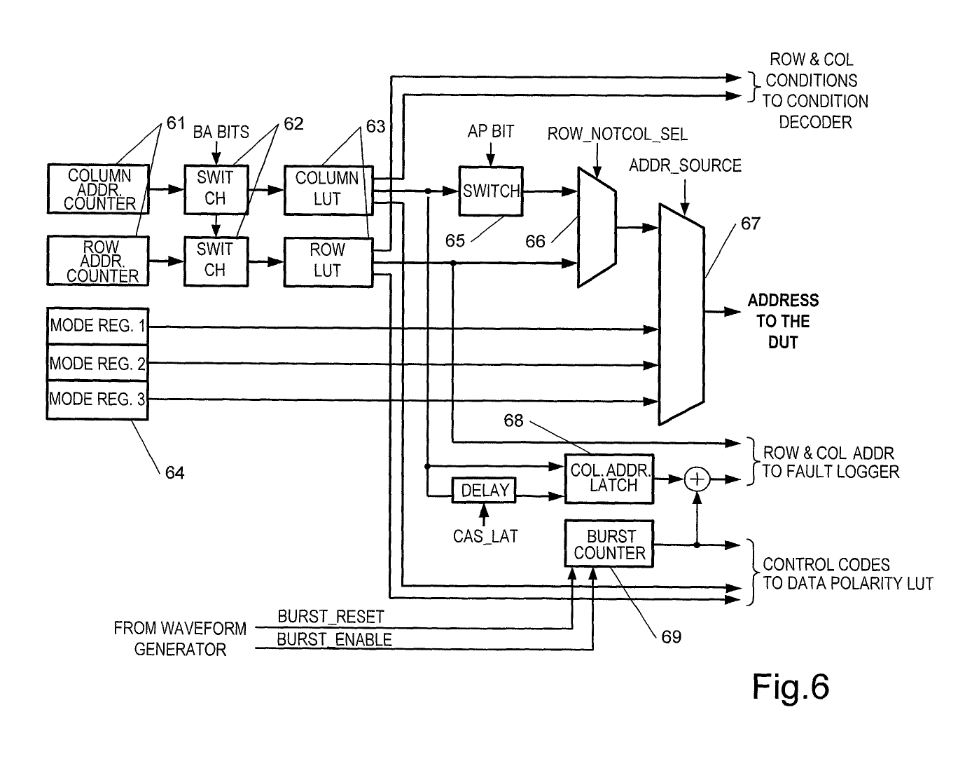

According to the present invention, waveform generator 22 and data generator 24 are operable at a low frequency and provided with respective multiplexers 31 and 32. The address generator 23 is provided with synchronisation circuit 33 as explained in detail later with reference to FIG. 6. To achieve the highest possible data rate, the waveform generator 22, data generator 24 and address generator 23 are made preferably without speed-limiting feedbacks. The only long-loop feedback is implemented in the Instruction sequencer 21.

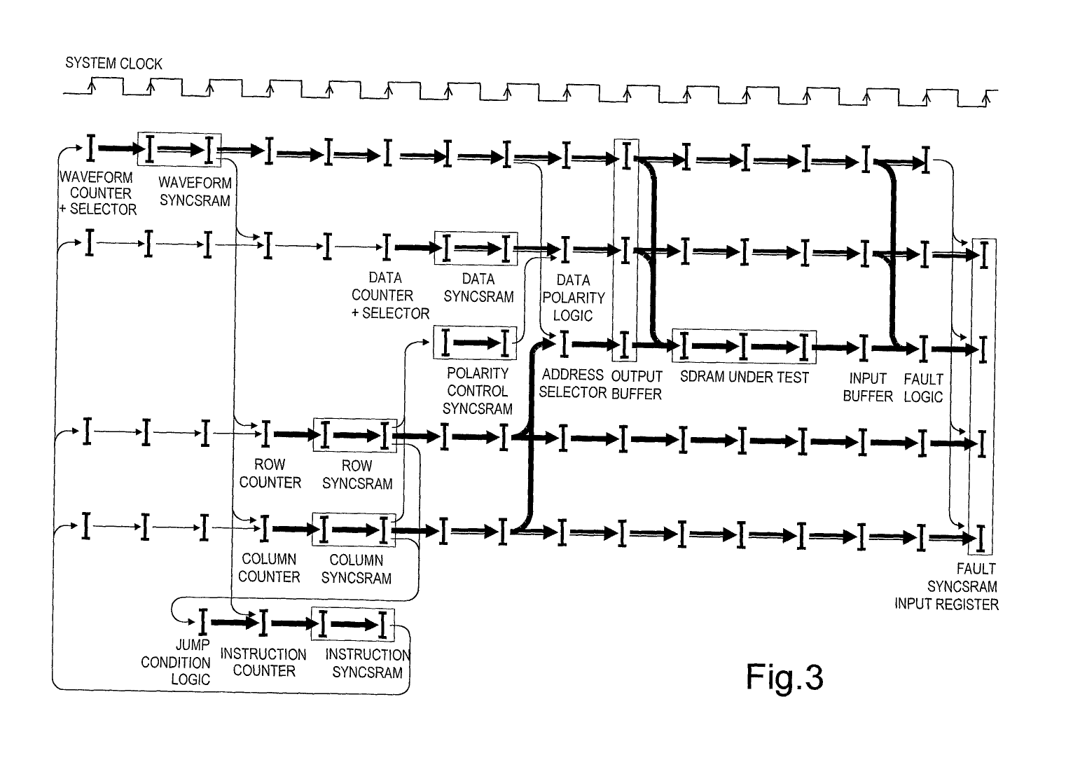

A simplified timing model of the test generator and fault logger is presented in FIG. 3. The structure is shown stretched along the time axis. Symbols like “I” mean registers with or without additional functions. If no name is provided for a register, then it is simply a pipeline stage without extra logic. Wide arrows show the main flow in the pipeline. Double arrows show operations performed at a low frequency. Thin arrows show control signals from one flow to another. This timing model shall be considered only as illustrative, as many details are omitted to prevent it getting too bulky. Multiple cross-coupled pipelines are shown, in which different actions are taken in appropriate timing positions.

Referring back to FIG. 2, instruction sequencer 21 controls behaviour of most of the other units of the test generator to perform test algorithms. An algorithm is presented as a set of instructions executed one at a time. A single instruction generally corresponds to multiple operations performed at the DUT. Instructions are typically stored in an instruction RAM as 48-bit words.

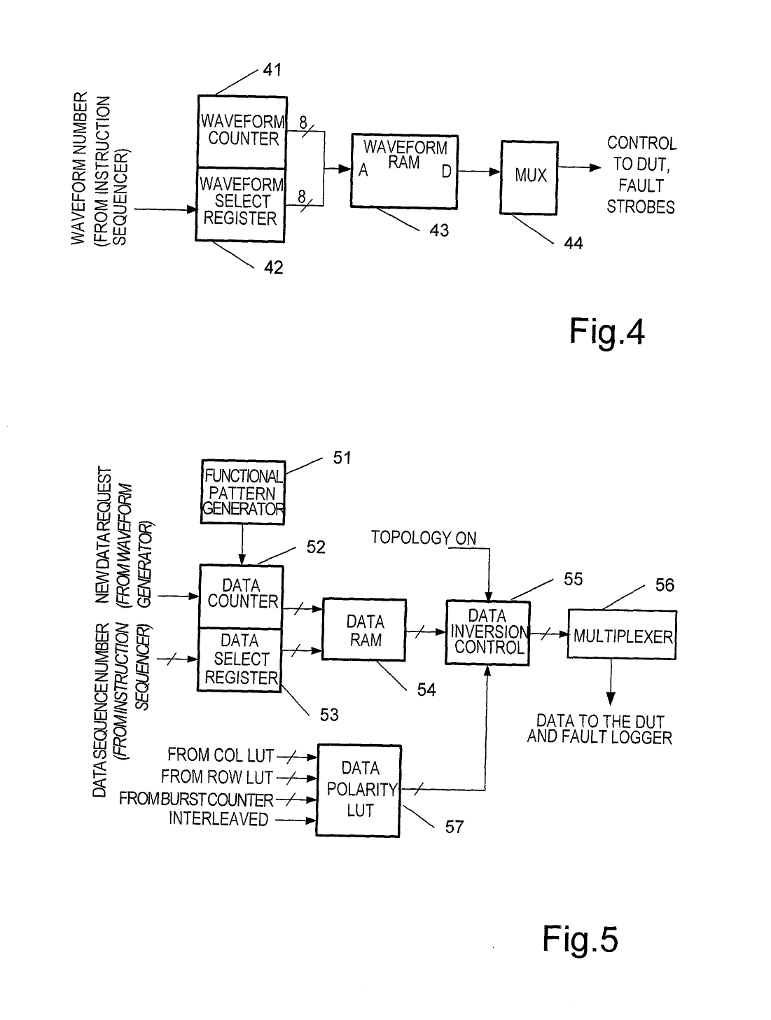

A functional diagram of waveform generator 22 is presented in FIG. 4. Signal patterns are stored in waveform RAM 43 and are extracted under control of two pointers: waveform counter 41 and waveform select register 42 which operate at a low frequency. The result data are fed to multiplexer 44 which supplies data at full frequency to the DUT.

Signals generated by the waveform generator 22 are primarily specified to cover requirements of control 16M, 64M and 256M SDRAMs and SGRAMs (Synchronous Graphics RAM) in configurations of up to 16 banks and up to 36 bits width. Another bunch of signals is provided to drive other units in the tester. Some spare signals are reserved for further extensions. Waveforms are stored in the waveform RAM 53 as 32-bit words, one word per clock period at the DUT.

Data generator 24 is intended to provide data to write into the DUT in write operations, and to compare with read-back data during verify operations. The data generator has two operating sub-modes: functional and algorithmic. In a functional sub-mode the data is generated as a purely combinatorial function of current address, regardless of the test algorithm. In the algorithmic sub-mode the data is generated by an algorithm implemented in the test and can be independent of the address. The data generator operates at low frequency.

In FIG. 5, a functional diagram of the data generator 24 is presented. The data words are stored in data RAM 54 and are extracted under control of two pointers: the data counter 52 and the data select register 53. The data select register 53 is controlled by the instruction sequencer 21 from FIG. 2 and selects 1 of 256 pages of data. Data counter 52 is controlled by the waveform generator 22, when in algorithmic sub-mode, or by the functional pattern generator (FPG) 51, when in functional sub-mode.

The test data generated in the way described above is then subjected to topology mapping. This allows the data lines to be inverted based on a function of the row and column addresses. The implementation in hardware is a two-stage process. The first stage is to generate 8 intermediate terms, 4 of these are arbitrary functions of row address only and 4 are arbitrary functions of column address only. The second stage is to generate an invert control 55 that is an arbitrary function of the 8 intermediate terms and contents of the Burst Counter.

The data is processed at a low frequency and is fed to a multiplexer 56 that provides data to the DUT at full frequency.

A functional diagram of the address generator 23 is presented in FIG. 6. As shown in the figure, the address generator supplies address information of different kinds to different destinations.

The address generator comprises Row and Column counters 61, which operate at a low frequency and which primary function is generating test addresses according to a test algorithm to apply to the DUT. A test address is initially generated by two 16-bit counters, one for Row and one for Column address.

The address counters 61 are supposed to directly generate physical addresses to be applied to the DUT, such as DRAM matrix within a SDRAM chip. The subsequent look-up tables (LUT) 63 convert physical addresses to logical addresses, which are applied to the chip. Within the chip the logical address is back converted to physical address before applying to the DRAM matrix. Thus, look-up tables perform logical function complementary to that of the on-chip scrambling logic.

Besides logical address, each address LUT has two extra output fields. One 4-bit field provides condition flags for conditional operations of the instruction sequencer 21 from FIG. 2. Another 4-bit field provides control codes for data autopolarity circuitry in the data generator 24.

According to the present invention, it is not required to generate different addresses for different banks at the same time, so that there is no need to generate new Row or Column Address at every clock cycle. This means that the requirements for the address counters rate can be reduced and there is no need to update them at full frequency; running at half frequency would suffice. For this reason only EVEN words of the Waveform are sampled for NEW_COL_ADDR_B and NEW_COL_ADDR_S bits.

It shall be noted that, according to the invention, a synchronisation means are provided which is implemented in the present example scheme as a burst counter 69 which runs at full frequency to allow read/write operations at full data rate. Thus, BURST_RESET and BURST_ENABLE bits are valid in both even and odd Waveform words.

Even though the Row and Column counters 61 update only on even clock periods, the addresses can still be applied via multiplexers 66 and 67 to the DUT on any clock period.

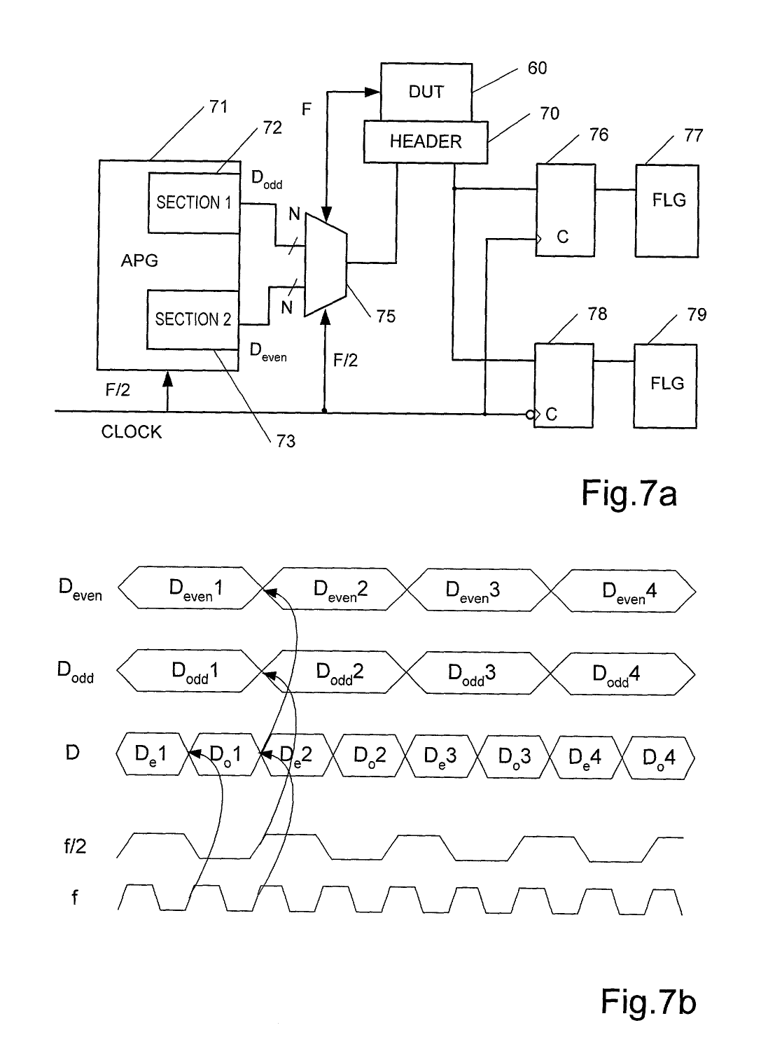

In FIG. 7a a diagram is shown illustrating a test system according to the invention.

A test generator 71 according to the present example is implemented as an algorithmic pattern generator combining logic units discussed in detail above. The test generator has a plurality of test data generating sections (in FIG. 7a, only two data generating sections 72 and 73 are shown to simplify the explanations). Each of said data generating sections generates data at half frequency F/2, for example, data generator 72 generates even data words, and data generator 73 generates odd data words as shown in timing diagram in FIG. 7b. Both data flows are fed to multiplexer 75 at half frequency, while multiplexer 75 operating at full clock selects data from data generating section 72 at even clock cycles and data from the data generating section 73 at odd clock cycles, thereby providing DUT with a flow of data at full frequency.

Data from the DUT is supplied in a similar manner in two flows to fault logic devices 77 and 79 via registers 76 and 78 that form a demultiplexer in such a manner that register 76 latches data at even clock cycles and register 78 latches data at odd clock cycles as well illustrated in timing diagram on FIG. 7b.

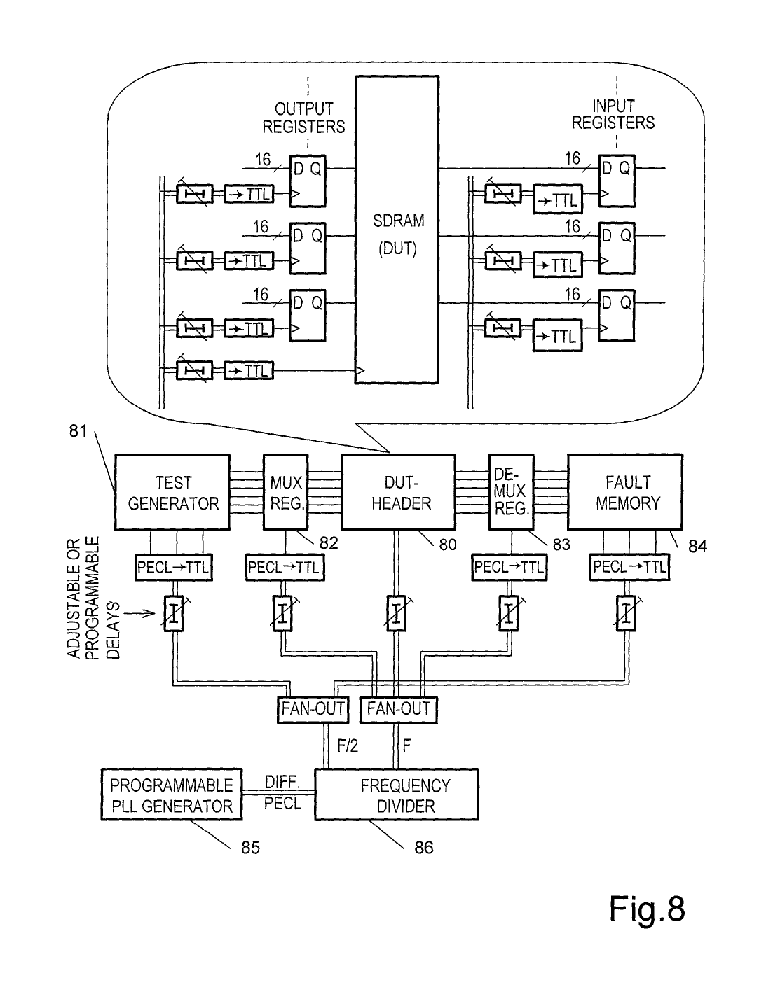

A detailed example embodiment of the test system according to the invention is shown in FIG. 8.

A test generator 81 having a plurality of test data generating sections (not shown) supplies test data via multiplexer 82 to DUT 80. The resulted data from the DUT is provided via demultiplexer 83 to fault memory 84. As shown in the figure, data processing stages including test data generation in test generator 81 and fault analysis in fault memory 84, is performed at a low frequency, while both multiplexer 82 and demultiplexer 83, as well as DUT 80, operate at full frequency that enhances greatly the speed of processing.

Fault memory 84 detects faults as mismatch of the test data provided by the test generator, and the data read back from the DUT. According to the present invention, fault data is read from the device under test at full speed, while the data flow is divided into two flows, one being via fault logic device 17 and another via fault logic device 19. Alternatively, the number of banks may be four and more.

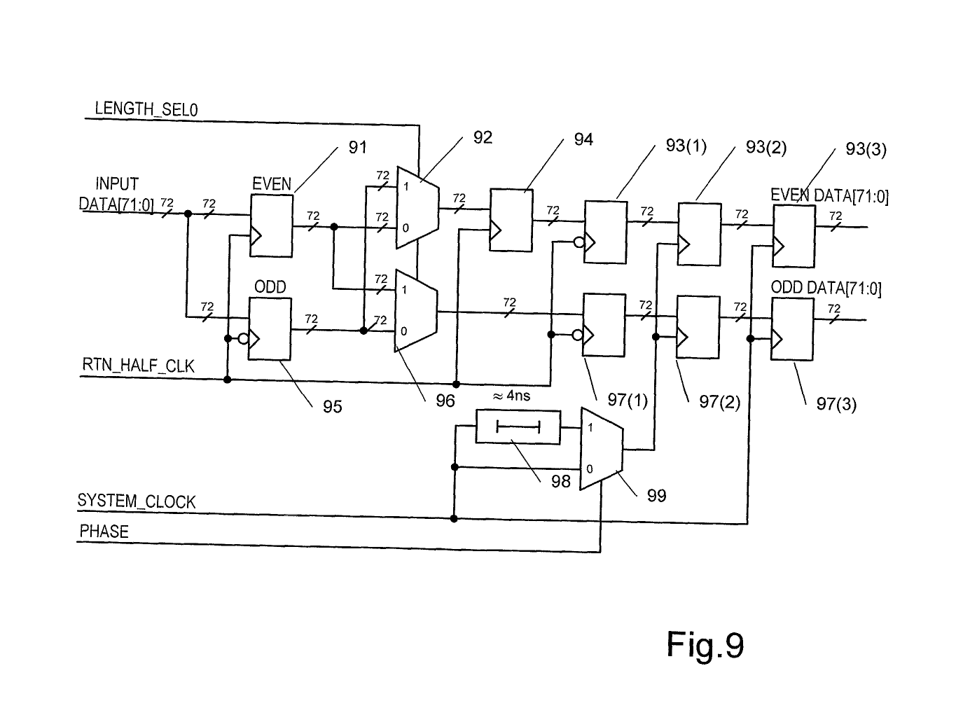

In FIG. 9, an input stage circuit for receiving signals from the DUT is shown in more detail. The data is coming from the DUT at full frequency and processed in the input stage circuit at half frequency. The input stage performs the following functions:

receiving input data on both edges of RTN_HALF_CLK clock;

providing +0 or +1 of additional latency measured at full speed and controlled by Length_Sel0 signal provided by test generator 11;

resynchronising received data to the rising edge of system clock signal.

In FIG. 9, registers 91 and 95 are latching data from the DUT as described with reference to FIG. 7a. Data are received on both edges of RTN_HALF_CLK clock signal and processed in two halves with twice lower frequency.

Multiplexers 92 and 96, under the control of length selection signal coming from the APG, and in combination with register 94, regulate the pipeline length to provide even data coming from the DUT are read at even cycles and odd data coming from the DUT are read at odd cycles. Register 94 delays even data for one clock period.

A resynchronisation circuit 98, 99 provides phase shift of a system clock to synchronise input data coming at half clock to the system clock.

Resynchronisation logic is required to support stable operation with all possible round trip delay that is a difference between the way from the test generator 11 from FIG. 1 to fault counters directly and the way trough the DUT. This delay depends on many different factors, such as type of header, frequency, vernier's settings, temperature and so on.

A series of parallel registers 93(1), 93(2), 93(3) and 97(1), 97(2), 97(3) provide the data are received outside the metastability region of flip-flop operation. Value of phase bit should be calculated to provide most stable transfer from one register to another.

Also compensation of proper number of pipeline stages can be provided by adjustment of pipeline length in the test generator.

Although the present invention and its advantages have been described in detail, it should be understood that various changes, substitutions and alterations can be made herein without departing from the spirit and scope of the invention as defined by the appended claims.

What is claimed:

1. A data processing system comprising:
a data transferring apparatus having data input and data output; a plurality of data transferring sections operable in parallel for transferring data, and a circuit for synchronising said parallel data transferring sections; and
a programmable frequency clock generator for generating a clock signal, wherein said programmed frequency includes a full-frequency and a low-frequency, the low frequency being a quotient of the full frequency and the number of said data transferring sections;
wherein said data transferring sections operate at said low frequency; while said input and output data are provided at said full frequency.

2. The data processing system according to claim 1, wherein said data transferring sections are data transmitters.

3. The data processing system according to claim 1, further comprising a multiplexer for receiving data from said data transferring sections at said low frequency and providing output data at said full frequency.

4. The data processing system according to claim 1, when used as a test system, wherein said data is transferred at said full frequency for accessing a memory device under test.

5. The data processing system according to claim 1, wherein said data transferring sections are data receivers.

6. The data processing system according to claim 1, wherein the data transferring apparatus comprises a plurality of data transmitting sections and a plurality of data receiving sections, wherein said data transmitting sections and said data receiving sections are operable at said low frequency; while said output and input data is transferred at said full frequency.

7. The data processing system as claimed in claim 1, wherein said low frequency is equal to a half of said full frequency.

8. The data processing system as claimed in claim 1, wherein said low frequency is equal to one forth of the full frequency.

9. The data processing system as claimed in claim 1, further comprising a resynchronisation circuit for resynchronising data received at low frequency to a system clock signal of full frequency.

10. A method of data processing comprising the steps of:
providing input data and output data;
transferring data through a plurality of parallel data transferring channels, wherein the data transfer additionally comprises synchronising said parallel data transferring channels;
generating clock signals of programmable frequency, wherein said programmed frequency includes full-frequency and low-frequency, the low frequency being a quotient of the full frequency and the number of said data transferring channels,
wherein said operations of data transfer are performed at said low frequency, while said input and output data are provided at said full frequency.

11. The method of data processing according to claim 10, wherein the data transferring sections are data transmitters, the method further comprising multiplexing data received from said data transmitters at said low frequency and providing multiplexed output data at said full frequency.

12. The method of data processing according to claim 10, wherein the data at said full frequency are provided for accessing memory device under test.

13. The method of data processing according to claim 10, wherein the data transferring sections are data receivers comprising a plurality of registers for latching data from a memory device under test and the latched fault data are supplied to a plurality of fault logic devices.

14. The method of data processing according to claim 10, comprising the steps of transmitting data, latching transmitted data and supplying latched data to a plurality of receiving logic devices; wherein said operations of data transmission, latching data and receiving data are performed at said low frequency; while said input and output data are provided at said full frequency.

15. The method of data processing according to claim 1, wherein said low frequency is equal to a half of said full frequency, for SDRAM memories.

16. The method of data processing according to claim 1, wherein said low frequency is equal to one forth of the full frequency, for DDR memories.

17. The method of data processing according to claim 1, further comprising a step of resynchronisation of data received at low frequency to a system clock signal of full frequency.

18. A test system comprising:
an algorithmic pattern generator having a plurality of test data generating sections operable in parallel for generating test data for accessing a memory device under test, wherein the pattern generator additionally comprises a circuit for synchronising said parallel data generating sections;
a programmable frequency clock generator for generating a clock signal, wherein said programmed frequency includes a full-frequency and a low-frequency, the low frequency being a quotient of the full frequency and a number of said test data generating sections;
a multiplexer that receives said test data from said data generating sections at said low frequency and provides multiplexed data for accessing DUT at said full frequency;
a plurality of registers for latching data from the DUT and supplying latched fault data to a plurality of fault logic devices;
wherein said test data generating sections, said registers and said fault logic devices operate at said low frequency; while said device under test is accessed at said full frequency.

19. The test system as claimed in claim 18, wherein said low frequency is equal to a half of said full frequency, for example, for SDRAM memories.

20. The test system as claimed in claim 18, wherein said low frequency is equal to one forth of the full frequency, for DDR memories.
